(19) United States
(12) Patent Application Publication
(10) Pub. No.: US 2015/0179571 A1
(43) Pub. Date: Jun. 25, 2015

(54) METAL INTERCONNECT STRUCTURES AND FABRICATION METHOD THEREOF

(71) Applicants: Semiconductor Manufacturing International (Beijing) Corporation, Beijing (CN); Semiconductor Manufacturing International (Shanghai) Corporation, Shanghai (CN)

(72) Inventors: XIANYONG PU, Shanghai (CN); ZONGGAO CHEN, Shanghai (CN); GANGNING WANG, Shanghai (CN); YIQUN CHEN, Shanghai (CN)

(73) Assignees: Semiconductor Manufacturing International (Beijing) Corporation; Semiconductor Manufacturing International (Shanghai) Corporation

(21) Appl. No.: 14/459,425

(22) Filed: Aug. 14, 2014

(30) Foreign Application Priority Data
Dec. 20, 2013 (CN) 201310712084.7

(51) Int. Cl. H01L 23/522; H01L 21/768; H01L 23/532

(52) U.S. Cl. CPC H01L 23/5226; H01L 23/53223; H01L 23/53238; H01L 23/53266; H01L 21/76846; H01L 21/76879

(57) ABSTRACT

A method is provided for fabricating a metal interconnection structure. The method includes providing a semiconductor substrate having an active region and an isolation structure surrounding the active region; and forming a metal layer on a surface of the semiconductor substrate. The method also includes forming a metal silicide layer on the active region by a reaction of the metal layer and material of the active regions; and forming an inter metal connection layer electrically connecting with the active regions on the isolation structure. Further, the method includes forming a dielectric layer covering the metal silicide layer, the isolation structure and the inter metal connection layer on the semiconductor substrate; and forming a metal contact via electrically connecting with the active region through the inter metal connection layer in the dielectric layer.

### CROSS-REFERENCES TO RELATED APPLICATIONS

This application claims the priority of Chinese patent application No.

201310712084.7, filed on Dec. 20, 2013, the entirety of which is incorporated herein by reference.

### FIELD OF THE INVENTION

The present invention generally relates to the field of semiconductor technology and, more particularly, relates to metal interconnection structures and fabrication techniques thereof.

### BACKGROUND

With the rapid development of the manufacturing technology of integrated circuits (ICs), the critical dimension of MOS transistors has become smaller and smaller. According to the scaling down principle, when the total size of CMOS transistors is shrunk, the size of the source region, the drain region, the gate structure, and vias, etc. is also shrunk accordingly.

In the logic circuit region of an IC chip, the integration level of transistors is relatively high. In order to reduce the area of the logic circuit region, the distance between adjacent transistors is relatively small. However, it may cause some difficulties to form a metal contact hole in the active region.

FIGS. 1˜2 illustrate existing static random access memory (SRAM) units with metal interconnection structures. FIG. 2 is a cross-section view of a SRAM unit with a metal interconnection at the circled region shown in FIG. 1.

As shown in FIGS. 1˜2, the static SRAM units are surrounded by a shallow trench isolation (STI) structure 10. Because the integration level of the SRAM is relatively high, the distance between adjacent SRAM units may be relatively small. Further, the size of the active region 20 of the SRAM may also be relatively small. The metal contact via 30 on the surface of the active regions 20 serves as interconnection structures to connect the active region 20 with other devices and/or structures.

As shown in FIG. 2, because the distance between adjacent active regions 20 of the SRAMs is relatively small, the size of the active region 20 is also relatively small, the size of the metal contact via 30 may be relatively large because of the limitation of the photolithography process; the active region 20 may be unable to surround the contact via 20.

Further, the isolation structures 10 and the dielectric layer 40 may be made of a same material, such as silicon oxide, etc. During a subsequent etching process for forming a contact hole used to form the conductive via 30 in the dielectric layer 40, the etching rate may be relatively large, thus the isolation structure 10 at the edge of the active region 20 may be overly etched with a certain depth; and an undercut may be caused at the edge of the active region 20. Therefore, a leakage current may be generated at the edge of the active region 20 because the conductive via 30 may connect with the semiconductor substrate; and the yield and the stability of the semiconductor device may be affected. The disclosed device structures and methods are directed to solve one or more problems set forth above and other problems.

### BRIEF SUMMARY OF THE DISCLOSURE

One aspect of the present disclosure includes a method for fabricating a metal interconnect structure. The method includes providing a semiconductor substrate having an active region and an isolation structure surrounding the active region; and forming a metal layer on a surface of the semiconductor substrate. The method also includes forming metal silicide layers on the active region by a reaction of the metal layer and material of the active region; and forming an inter metal connection layer electrically connecting with the active region on the isolation structure. Further, the method includes forming a dielectric layer covering the metal silicide layer, the isolation structure and the inter metal connection layer on the semiconductor substrate; and forming a metal contact via electrically connecting with the active region through the inter metal connection layer in the dielectric layer

Another aspect of the present disclosure includes a metal interconnect structure. The metal interconnect structure includes a semiconductor substrate having active regions and an isolation structure surrounding the active regions; and a metal silicide layer formed on the active regions. The metal interconnect structure also includes an inter metal connection layer electrically connecting with the active region formed on the isolation structure; and a dielectric layer covering the metal silicide layer, the isolation structure and the inter metal connection layer formed on the semiconductor substrate. Further, the metal interconnect structure includes a metal contact via electrically contacting with the inter metal connection layer formed in the dielectric layer.

Other aspects of the present disclosure can be understood by those skilled in the art in light of the description, the claims, and the drawings of the present disclosure.

### BRIEF DESCRIPTION OF THE DRAWINGS

FIG. 1 illustrates existing static random access memories with metal interconnection structures;

FIG. 2 illustrates a cross-section view of an existing static random access memory with an metal conductive via shown in the circled region in FIG. 2

FIGS. 3˜11 illustrate semiconductor structures corresponding to certain stages of an exemplary fabrication process of a metal interconnect structure consistent with the disclosed embodiments;

FIG. 12 illustrates a static random access memory consistent with the disclosed embodiments; and

FIG. 13 illustrates an exemplary fabrication process of a metal interconnect structure consistent with the disclosed embodiments.

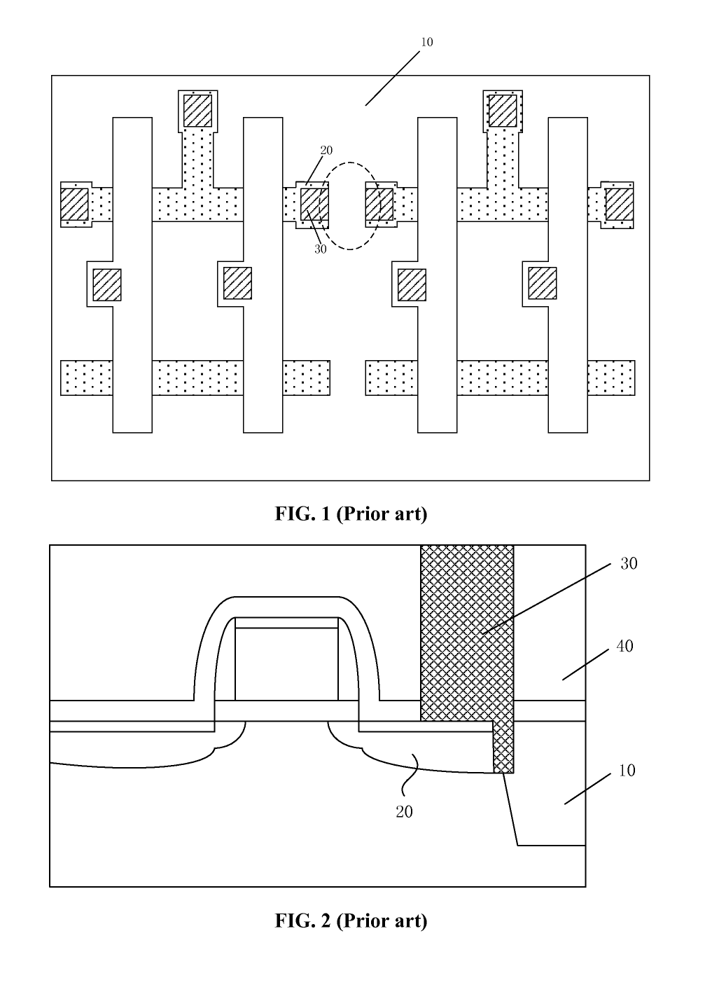

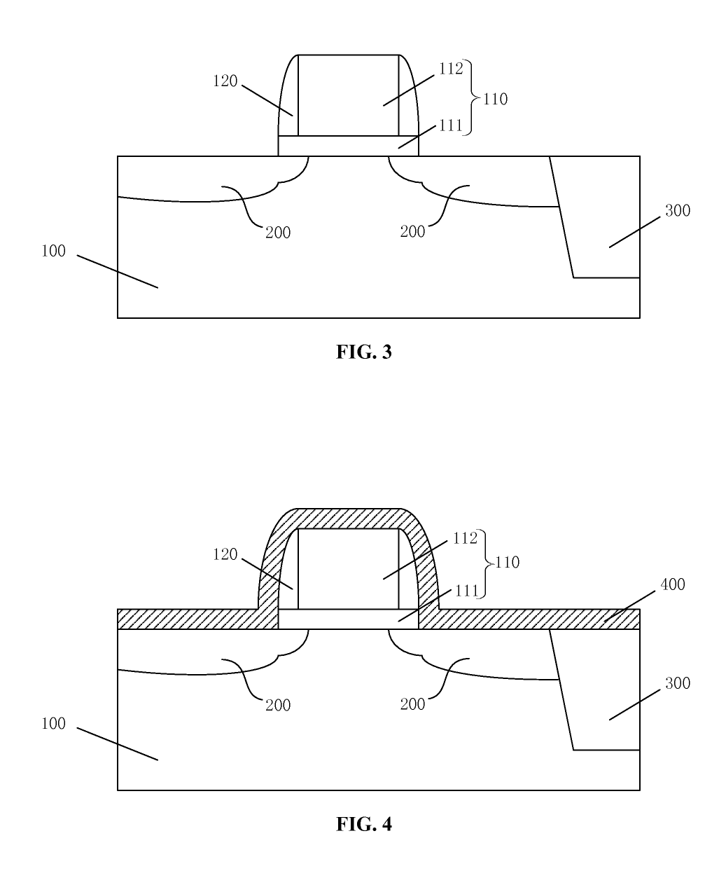

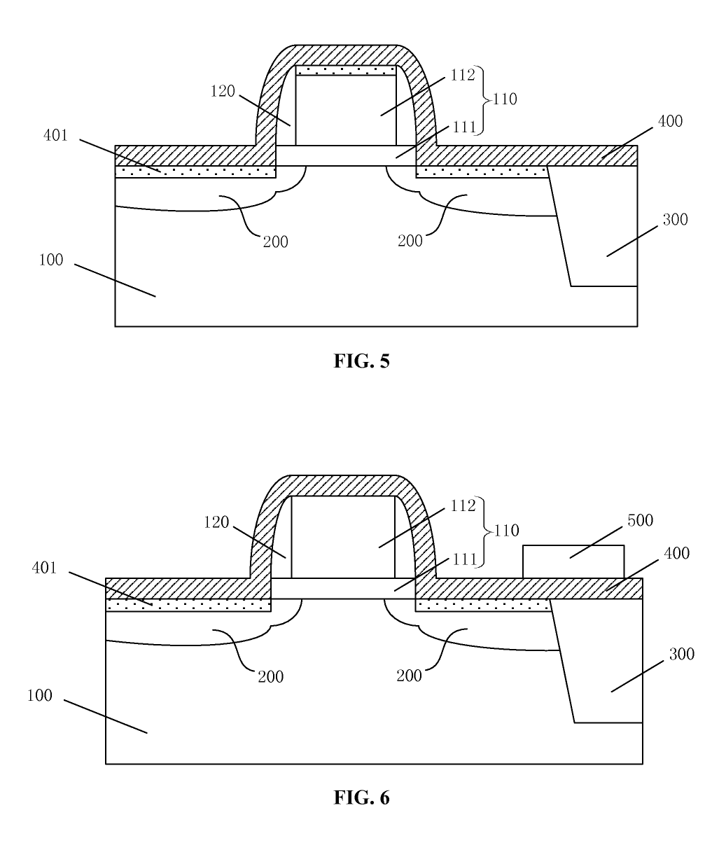

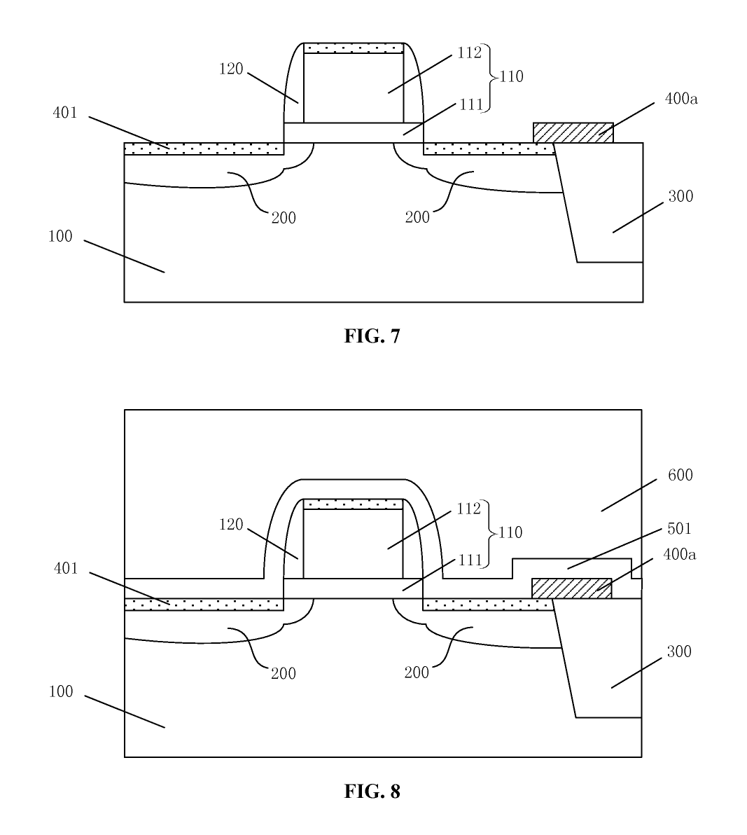

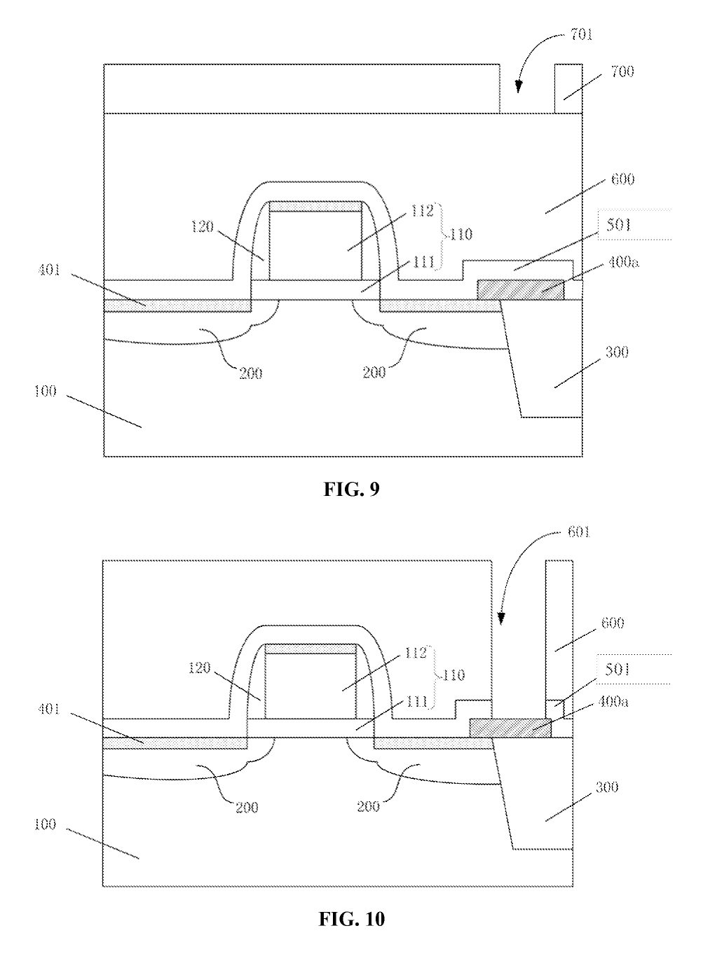

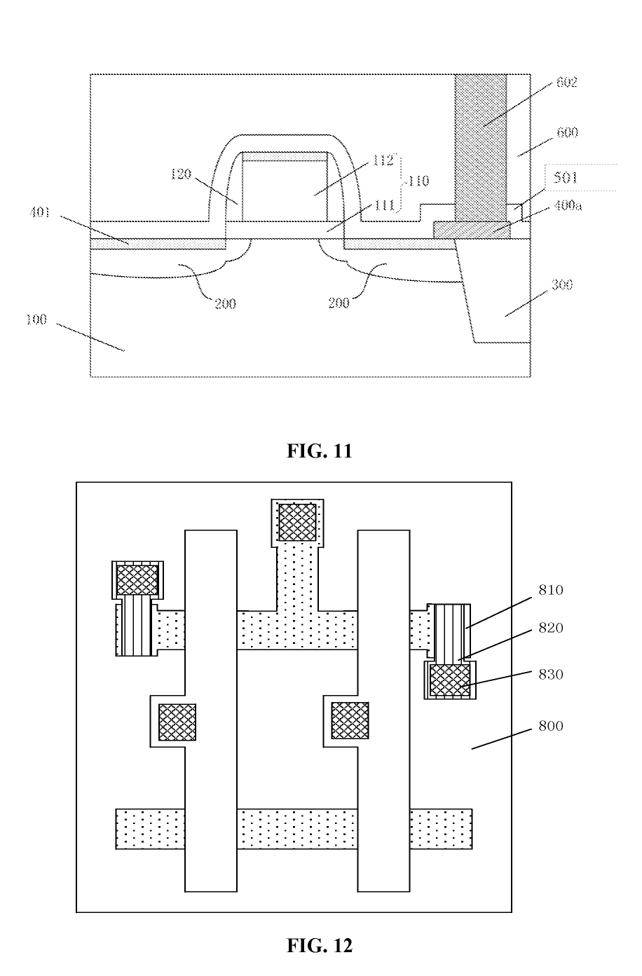

### DETAILED DESCRIPTION

Reference will now be made in detail to exemplary embodiments of the invention, which are illustrated in the accompanying drawings. Wherever possible, the same reference numbers will be used throughout the drawings to refer to the same or like parts.

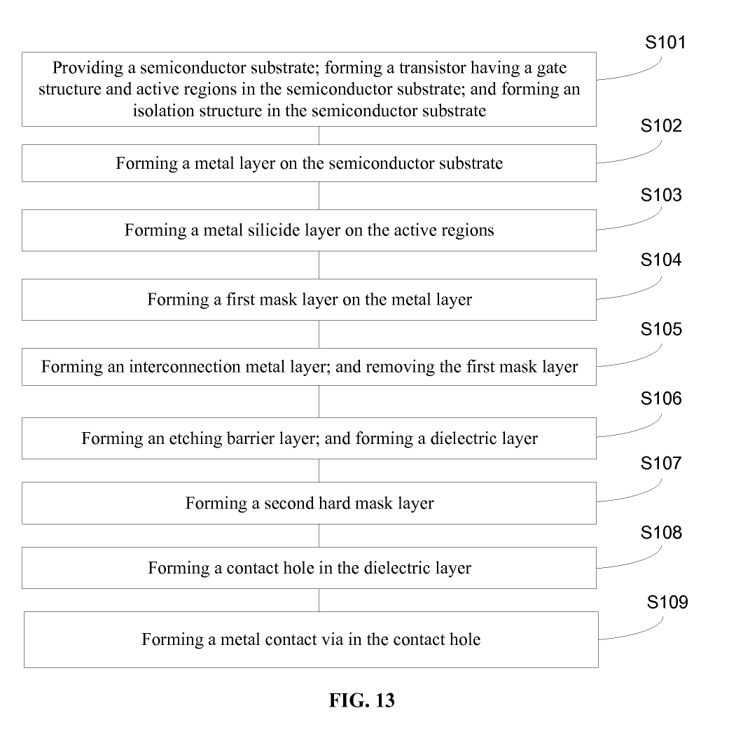

FIG. 13 illustrates an exemplary fabrication process of a metal interconnect structure consistent with disclosed embodiments; and FIGS. 3˜11 illustrate semiconductor structures corresponding to certain stages of the exemplary fabrication process.

As shown in FIG. 13, at the beginning of the fabrication process, a semiconductor substrate with certain structures is provided (S101). FIG. 3 illustrates a corresponding semiconductor structure.

As shown in FIG. 3, a semiconductor substrate 100 is provided; active regions 200 are formed in the semiconductor substrate 100. Specifically, a transistor may be formed in the semiconductor substrate 100. The transistor may include a gate structure 110 and source drain regions at both sides of the gate structure 110. In one embodiment, as shown in FIG. 3, the source/drain regions may be the active regions 200. A metal conductive via may be subsequently formed on the surface of one active region 200 at one side of the gate structure 110.

The semiconductor substrate 100 may include any appropriate semiconductor materials, such as silicon, silicon on insulator (SOI), germanium on insulator (GOI), silicon germanium, carborundum, indium antimonide, lead telluride, indium arsenide, indium phosphide, gallium arsenidie, gallium antimonite, or alloy semiconductor, etc. In one embodiment, the semiconductor substrate 100 is made of silicon. The semiconductor substrate 100 provides a base for subsequent processes and structures.

The gate structure 110 may include a gate dielectric layer 111 formed on the surface of the semiconductor substrate 100; and a gate electrode 112 formed on the surface of the gate dielectric layer 111.

The gate dielectric layer 111 may be made of any appropriate material, such as silicon oxide, silicon nitride, or silicon oxynitride, etc. In one embodiment, the gate dielectric layer 111 is made of silicon oxide. In certain other embodiments, the gate dielectric layer 111 may be high dielectric constant (high-K) material including HfO₂, ZrO₂, or HfSiO₃, etc.

The gate electrode layer 112 may be made of any appropriate material, such as poly silicon, doped poly silicon, or metal material, etc. In one embodiment, the gate electrode layer 112 is made of poly silicon. In certain other embodiments, the gate electrode layer 112 may be made of metal material including Al, Ni, W, or TiN, etc.

Further, as shown in FIG. 3, sidewall spacers 120 may be formed on the side surfaces of the gate structure 110. The sidewall spacers 120 may be used to protect the gate electrode 112. The sidewall spacers 120 may be single layer structures or multiple-stacked structures made of one or more of silicon oxide, silicon nitride, or silicon oxy nitride, etc.

Further, as shown in FIG. 3, an isolation structure 300 surrounding the active region 200 may be formed in the semiconductor substrate 100. In one embodiment, the isolation structure 300 may be a shallow trench isolation structure. The isolation structure 300 may be made of any appropriate material, such as silicon oxide, silicon nitride, or silicon oxynitride, etc. In one embodiment, the isolation structure is made of silicon oxide.

In certain other embodiments, static random access memories (SRAMs) may be formed in the semiconductor substrate 100, the active regions 200 may be the source region and/or the drain region of the transistor of the SRAMs.

In certain other embodiments, the active regions 200 may be other doping regions requiring metal conductive vias.

Returning to FIG. 13, after providing the semiconductor 100 having the fabricated structures, a metal layer may be formed (S102). FIG. 4 illustrates a corresponding semiconductor structure.

As shown in FIG. 4, a metal layer 400 is formed on the surface of the semiconductor substrate 100. The metal layer 400 may cover the surfaces of the source/drain region 200, the gate structure 110 and the isolation structure 300.

The metal layer 400 may be made of any appropriate material, such as Co, TiN, Ni, or Ti, etc. In one embodiment, the metal layer 400 is made of Co. The metal layer 400 may be used to subsequently form metal silicide layers on the surfaces of the source/drain region 200 and the gate structure 110 by reacting with the source drain/drain region 200 and the gate structure 110 during a thermal annealing process.

Various processes may be used to form the metal layer 400, such as a chemical vapor deposition (CVD) process, a physical vapor deposition (PVD) process, a thermal evaporation process, or a sputtering process, etc. In one embodiment, the metal layer 400 is formed by a sputtering process.

Returning to FIG. 13, after forming the metal layer 400, a metal silicide layer maybe formed (S103). FIG. 5 illustrates a corresponding semiconductor structure.

As shown in FIG. 5, a metal silicide layer 401 is formed on the surfaces of the active regions 200 and the gate electrode layer 112. The metal silicide layer 401 may be used to reduce the contact resistance between the source/drain region 200 and a subsequently formed metal contact via, thus the source/drain region of the transistor may be improved.

The metal silicide layer 401 may be formed by a thermal annealing process. During the thermal annealing process, the metal of the metal layer 400 may react with the atoms in the source/drain regions 200 and the gate electrode layer 112; and the metal silicide layer 401 is formed.

The instruments for the thermal annealing process may include a tube furnace, or a rapid thermal treatment instrument, etc. The protection gas of the thermal annealing process may be high purity nitrogen. The thermal annealing temperature may be in a range of approximately 200° C.˜1100° C. The thermal annealing time may be in a range of approximately 30 s˜120 s. Such parameters may cause the metal atoms of the metal layer 400 to react with the silicon atom; and the metal silicide layer 401 is formed. Because, the metal layer 400 may only react with silicon to form the metal silicide layer 401, the metal silicide layer 401 may only be formed on the source/drain region 200 and the top surface of the gate electrode layer 112. That is, the metal silicide layer 401 may not be formed on other region, such as the surface of the isolation structure 300, etc.

In one embodiment, the metal silicide layer 401 is made of cobalt silicide. In certain other embodiments, the metal silicide layer 401 may be tantalum-based metal silicide, titanium-based metal silicide, tungsten-based metal silicide, or nickel-based metal silicide, etc.

Returning to FIG. 13, after forming the metal silicide layer 401, a first mask layer may be formed (S104). FIG. 6 illustrates a corresponding semiconductor structure.

As shown in FIG. 6, a first mask layer 500 is formed on the surface of the metal layer 400. The first mask layer 500 may cover a portion of metal layer 400 above a portion of the source/drain region 200 and a portion of the isolation structure 300 at one side of the portion of the source/drain region 200.

The first mask layer 500 may be a single layer structure, or a multiple-stacked structure. In one embodiment, the mask layer 500 is a multiple stacked structure made of silicon oxide, bottom anti-reflection layer and photoresist. The mask layer 500 may also be made of one or more of photoresist, silicon oxide, silicon nitride, or silicon oxynitride, etc.

In one embodiment, the first mask layer 500 is a photoresist layer, a process for forming the first mask layer 500 may include forming an initial photoresist layer on the surface of the metal layer 400; and followed by exposing and developing the initial photoresist layer. A portion of the initial photoresist layer on the portion of metal layer 400 above the portion of the source/drain region 200 and the portion of the isolation structure 300 at one side of the source/drain region 200 may be kept to be used as the first mask layer 500. The first mask layer 500 may be used to define the position and the size of the subsequently formed inter connection metal layer.

Returning to FIG. 13, after forming the first mask layer 500, a portion of the metal layer 400 may be removed; and the first mask layer 500 may be removed (S105). FIG. 7 illustrates a corresponding semiconductor structure.

As shown in FIG. 7, a portion of the metal layer 400 without being covered by the first mask layer 500 is removed; and an inter metal connection layer 400a is formed. The inter metal connection layer 400a may be formed by etching the metal layer 400 using the first mask layer 500 as an etching mask.

Various processes may be used to remove the portion of the metal layer 400 without being covered by the first mask layer 500, such as a dry etching process, a wet etching process, or an ion beam etching process, etc. In one embodiment, the portion of the metal layer 400 without being covered by the first mask layer 500 is removed by a wet etching process.

The etching solution of the wet etching process may be a mixture of NH₄OH, H₂O₂, and H₂O, etc. The ratio of NH₄OH, H₂O₂ and H₂O may be in a range of approximately 1:1:5˜1:2:7. In certain other embodiments, other appropriate etching solutions may also be used for the wet etching process, such as a mixture of HF and H₂O₂, etc.

Because of the protection of the first mask layer 500, the portion of the metal layer 400 under the first mask layer 500 may not be removed, thus the inter metal connection layer 400a is may be formed.

Referring to FIG. 7, a portion of the inter metal connection layer 400a may be formed on the surface of the source/drain region 200; and may electrically connect with the source/drain region 200 through the metal silicide layer 401. Further, the other portion of the inter metal connection layer 400a may be formed on the isolation structure 300. A metal contact via may be subsequently formed on the inter metal connection layer 400a, thus the metal contact via may be electrically connected with the active region 200. The inter metal connection layer 400a may be formed on the isolation structure 300 near to the active region 200 with a relatively large area, thus the area of the inter metal connection layer 400a may be relatively large. After subsequently forming the metal contact via on the inter metal connection layer 400a, the metal contact via may be completely surrounded by the inter metal connection layer 400a on the isolation structure 300. That is, the metal contact via may be formed entirely on the top of the inter metal connection layer 400a instead of the active region 200; and/or only a portion (e.g., a small portion) of the metal contact via may be formed on the active region 200 with the rest of the inter metal connection layer 400a. Further, the size of the inter metal connection layer 400a is configured such that the inter metal contact via is completely surrounded by the inter metal connection layer 400a or by both the active region 200 and the inter metal connection layer 400a. Therefore, the undercut issue caused by directly forming the metal contact via on the active region 200 may be avoided.

Further, because the inter metal connection layer 400a may be on the surface of the isolation structure 300, even the subsequently formed metal contact via is not completely surrounded by the inter metal connection layer 400a, an over-etching caused by subsequently forming the metal contact via may only etch the isolation structure 300 because the isolation structure 300 is under the inter metal connection layer 400a; and the metal contact via may not contact with the semiconductor substrate 200. Thus, the leakage current between the metal contact via and the semiconductor substrate 100 may unlikely be formed; and the performance of the semiconductor device may not be affected.

Returning to FIG. 13, after forming the inter metal connection layer 400, an etching barrier layer may be formed (S106). FIG. 8 illustrates a corresponding semiconductor structure.

As shown in FIG. 8, an etching barrier layer 501 is formed on the surface of the semiconductor substrate 100. The etching barrier layer 501 may cover the source/drain regions 200, the surface of the gate structure 110 and the metal silicide layer 401, the sidewall spacers 120, the interconnection metal layer 400a and the isolation structure 300. Further, a dielectric layer 600 is formed on the surface of the etching barrier layer 501.

The etching barrier layer 501 may be used as an etching barrier layer for subsequently etching the dielectric layer 600 to form an etching hole. The etching barrier layer 501 may be made of any appropriate material, such as SiN, SiON, TiN, TaN, or WN, etc. In one embodiment, the etching barrier layer 501 is made of SiN. Various processes may be used to form the etching barrier layer 501, such as a CVD process, an FCVD process, or an ALD process, etc.

The dielectric layer 600 may be configured as an interlayer dielectric layer to isolate the transistor and subsequent formed semiconductor devices and the structures on the dielectric layer 600. A contact metal via may be subsequently formed in the dielectric layer 600 to connect with the active region 200.

The dielectric layer 600 may be made of any appropriate material, such as silicon oxide, silicon nitride, or silicon oxynitride, etc. In one embodiment, the dielectric layer 600 is made of silicon oxide.

Various processes may be used to form the dielectric layer 600, such as a CVD process, a PVD process, an FCVD process, etc. In one embodiment, the dielectric layer 600 is formed by a CVD process.

Returning to FIG. 13, after forming the dielectric layer 600, a second mask layer 700 may be formed (S107). FIG. 9 illustrates a corresponding semiconductor structure.

As shown in FIG. 9, a second mask layer 700 is formed on the dielectric layer 600. The second mask layer 700 may have an opening 701; and the opening 701 may expose a portion of the surface of the dielectric layer 600.

The second mask layer 700 may be made of any appropriate material, such as photoresist, silicon nitride, silicon oxide, etc. In one embodiment, the second mask layer 700 is a multiple-stacked structure including a silicon nitride layer, a bottom anti-reflection layer and a photoresist layer. In certain other embodiments, the second mask layer 700 may be a single layer structure.

In one embodiment, the second mask layer 700 is a photoresist layer. The photoresist layer may formed on the dielectric layer 600; and followed by exposing and developing the photoresist layer to form the opening 701, thus the second mask layer 700 with the opening 701 may be formed. The opening 701 may be above the inter metal connection layer 400a; and may be used to define the size and the position of the subsequently formed metal contact via.

The size of the opening 701 may be smaller than the size of the inter metal connection layer 400a on the isolation structure 300, so as that the size the subsequently formed metal contact via may also be smaller than the size of the inter metal connection layer 400a. Therefore, the metal contact via may be completely surrounded by the interconnection metal layer 400a or surrounded by the active region 200 and the inter metal connection layer 400a.

Returning to FIG. 13, after forming the second mask layer 600, a contact hole may be formed (S108). FIG. 10 illustrates a corresponding semiconductor structure.

As shown in FIG. 10, a contact hole 601 is formed in the dielectric layer 600. A portion of the surface of the interconnection metal layer 400a may be exposed by the contact hole 601; and the contact hole 601 may be used to subsequently form a metal contact via on the surface of the inter metal connection layer 400a. Further, the second mask layer 700 may be removed.

The contact hole 601 may be formed by etching the dielectric layer 600 along the opening 601. That is, the second mask layer 700 with the opening 701 may be used as an etching mask.

Various processes may be used to etch the dielectric layer 600 to form the contact hole 601, such as a dry etching process, a wet etching process, or an ion beam etching process, etc. In one embodiment, the contact hole 601 is formed by a dry etching process.

An etching gas of the dry etching process may include one or more of CF₄, CHF₃, and C₂F₆, etc. In one embodiment, the etching gas of the dry etching process is CF₄. A buffer gas may be He. The pressure of the dry etching process may be in a range of approximately 20 mTorr˜200 mTorr. The flow of CF₄ may be in a range of approximately 50 sccm˜1000 sccm. The flow of He may be in range of approximately 50 sccm˜1000 sccm.

Various processes may be used to remove the second mask layer 700, such as a dry etching process, a wet etching process, or a plasma ashing process, etc. In one embodiment, the second mask layer 700 is made of photoresist layer; a plasma ashing process may be used to remove the second hard mask layer 700 after forming the contact hole 601. In certain other embodiments, the second mask layer 700 is removed by a wet etching process.

Returning to FIG. 13, after forming the contact hole 601, a metal contact via may be formed (S109). FIG. 11 illustrates a corresponding semiconductor structure.

As shown in FIG. 11, a metal contact via 602 is formed on the inter metal connection layer 400a in the contact hole 601. The metal contact via 602 may electrically contact with the interconnection metal layer 400a.

The metal contact via 602 may be formed by filling the contact hole 601 with a metal material. Specifically, a process for forming the metal contact via 602 may include filling the contact hole 601 with a metal material; and followed by a chemical mechanical polishing (CMP) process. The metal material may fill up the contact hole 602 and cover the surface of the dielectric layer 600. The surface of the metal material may be planarized by the CMP process using the dielectric layer 600 as a stop layer. After the CMP process, the surface of the metal contact via 602 may level with the surface of the dielectric layer 600; and the metal contact via 602 may be formed.

In certain other embodiments, a process for forming the metal contact via 602 may include forming a diffusion barrier layer (not shown) on the surface of the dielectric layer 600 and the inner surface of the contact hole 601; forming the metal material on the surface of the diffusion barrier layer to fill up the contact hole 601; and planarizing the diffusion barrier layer and the metal material on the surface of the dielectric layer 600 by a CMP process using the dielectric layer 600 as a stop layer. Thus, the metal contact via 602 may be formed.

The metal material may be Cu, Al, or W, etc. Various processes may be used to fill the contact hole 601 with the metal material, such as a CVD process, an FCVD process or a sputtering process, etc.

The diffusion barrier layer may be used to prevent the metal atoms of the metal material from diffusing into dielectric layer 600. If the metal atoms diffuse into the dielectric layer 600, the isolation effect and the dielectric constant of the dielectric layer 600 may be affected; and a relatively large parasitic capacitance may be generated.

The diffusion barrier layer may be made of any appropriate material, such as TaN, or TiN, etc. Various processes may be used to form the diffusion barrier layer, such as a CVD process, a PVD process, or a sputtering process, etc.

The metal contact via 602 may be formed on the surface of the inter metal connection layer 400a; and a portion of the metal interconnection layer 400a may be formed on the surface of the source/drain region 200, thus, the metal contact via 602 may electrically connect with the source/drain region 200 through the interconnection metal layer 400a.

Further, the metal contact via 602 may not be directly formed on the surface of the source/drain region 200, thus an over-etching onto the source/drain region 200 may be avoided; and a leakage between the metal contact via 602 and the semiconductor substrate 100 may be prevented.

Further, a portion of the inter metal connection layer 400a may be formed on the isolation structure 300 surrounding the source/drain region 200; and the area of the portion of the inter metal connection layer 400 formed on the isolation structure 300 may be relatively large, thus the entire metal contact via may be on the inter metal connection layer 400a.

Further, because the inter metal connection layer 400a may be formed on the isolation structure 300, if the metal contact via is not completely surrounded by the inter metal connection layer 400a, a portion of the metal contact via 602 may be formed on the isolation structure. The isolation structure 300 may be an isolation structure between the metal contact via 602 and the semiconductor substrate 100, thus a leakage current between the metal contact via 602 and the semiconductor substrate 100 may be prevented; and the effect of the leakage current to the performance of the semiconductor device may be avoided.

Thus, a metal interconnection structure may be formed by the above disclosed processes and methods; and a corresponding metal interconnection structure is illustrated in

FIG. 11. The metal interconnection structure includes a semiconductor substrate 100 having active regions 200 configured as source/drain regions of a transistor; and an isolation structure 300 surrounding the active regions 200. The metal interconnection structure also includes a metal silicide layer 401 formed on the surface of the active region 200; and an inter metal connection layer 400a electrically connecting with the metal silicide layer 401 on the surface of the active region 200 formed on the isolation structure 300. Further, the metal interconnection structure includes a dielectric layer 600 covering the metal silicide layer 401, the isolation structure 300 and the inter metal connection layer 400a formed on the semiconductor substrate 100; and a metal contact via 602 electrical connecting with the active region 200 through the inter metal connection layer 400a.

FIG. 12 illustrates a static random access memory (SRAM) having a metal contact via 830 formed by the disclosed processes and methods. As shown in FIG. 12, an inter metal connection layer 820 is formed on the isolation structure 800 at one side of the active region 810. The inter metal connection layer 820 may be electrically contact with the active region 810; and the metal contact via may be formed on the inter metal connection layer 820.

The distance between adjacent SRAM units of the SRAM may be relatively small, thus the size of the active region 810 may also be relatively small. If the metal contact via 830 is directly formed on the active region 810, an over-etching may happen to the active region 810 during the processes for forming the metal contact via, such as an etching process for forming a contact hole, etc. Thus, the metal contact via 830 may contact with the semiconductor substrate of the SRAM, a leakage current may be generated between the metal contact via 830 and the semiconductor substrate.

If the inter metal connection layer 820 is formed on the surface of the isolation structure 800 at one side of the active region 810; and a portion of the inter metal connection layer 820 is also formed on the surface of the active region 810, thus the active region 810 may electrically contact with other devices and structures through the inter metal connection layer 820.

The inter metal connection layer 820 may be formed on a relatively large portion of the isolation structure 800 at one side of the active region 810, thus the metal contact via 830 may be completely on the surface of the inter metal connection layer 820; and a connection between the metal contact via 830 and the semiconductor substrate may be prevented. Therefore, the leakage current between the contact metal via 830 and the semiconductor substrate may be avoided.

The size and the position of the inter metal connection layer 820 may be adjusted according to device structures, so as that the metal contact via 830 may be formed on a relatively large portion of the isolation structure 800, thus bridge connections of the metal contact via 830 between adjacent active regions may be avoided. Such bridge connections may affect the device performance.

In certain other embodiments, the disclosed processes and methods may also be applied onto the logic circuits of IC chips. Active regions with relatively small distances may be electrically extended on isolation structures with relatively large area using inter metal connection layers; and then metal contact vias may be formed on the inter metal connection layers. Thus, the active regions may electrically connect with the metal contact vias by the inter metal connection layers.

The above detailed descriptions only illustrate certain exemplary embodiments of the present invention, and are not intended to limit the scope of the present invention. Those skilled in the art can understand the specification as whole and technical features in the various embodiments can be combined into other embodiments understandable to those persons of ordinary skill in the art. Any equivalent or modification thereof, without departing from the spirit and principle of the present invention, falls within the true scope of the present invention.

What is claimed is:

1. A method for fabricating a metal interconnection structure, comprising:
providing a semiconductor substrate having an active region and an isolation structure surrounding the active region;
forming a metal layer on a surface of the semiconductor substrate;
forming a metal silicide layer on the active regions by a reaction of the metal layer and material of the active regions;
forming an intermetal connection layer electrically connecting with the active regions on the isolation structure;
forming a dielectric layer covering the metal silicide layer, the isolation structure and the interconnection metal layer on the semiconductor substrate; and
forming a metal contact via electrically connecting with active region through the inter metal connection layer in the dielectric layer;
wherein the inter metal connection layer surrounds the metal contact via such that the metal contact is not in contact with the isolation structure or the semiconductor substrate to prevent a leakage current between the metal contact via and the semiconductor substrate.

2. The method according claim 1, wherein forming the interconnection metal layer further includes:
forming a first mask layer on the metal layer; and
removing a portion of the metal layer without being covered by the first mask layer to form the interconnection metal layer.

3. The method according to claim 1, wherein:
the metal silicide layer is formed by a thermal annealing process.

4. The method according to claim 1, wherein:
the metal contact via is completely formed on the inter metal connection layer; and
the metal contact via is electrically connected to the active region through the inter metal connection layer.

5. The method according to claim 1, before forming the dielectric layer, further including:
forming an etching barrier layer on the semiconductor substrate.

6. The method according to claim 1, wherein:
The inter metal connection layer is made of Co, TiN, Ni, or Ti.

7. The method according to claim 5, wherein:
the etching barrier layer is made of SiN.

8. The method according to claim 1, wherein forming the metal contact via further includes:
forming a second mask layer having an opening on the dielectric layer;
forming a contact hole exposing a surface on the inter metal connection layer in the dielectric layer by etching the dielectric layer along the opening; and
filling the contact hole with a metal material.

9. The method according to claim 8, wherein:
the metal material is made of Cu, Al, or W.

10. The method according to claim 8, before filling the metal contact hole, further including:
forming a diffusion barrier layer on an inner surface of the contact hole.

11. The method according to claim 10, wherein:
the diffusion barrier layer is made of TiN or TaN.

12. The method according to claim 3, wherein:
a temperature of the thermal annealing process is in a range of approximately 200° C.˜1100° C.; and
a time of the thermal annealing process is a range of approximately 30 s˜120 s.

13. The method according to claim 2, wherein:
the first mask layer is a multiple-stacked structure including a silicon oxide layer, a bottom anti-reflection layer and a photoresist layer.

14. The method according to claim 1, wherein:
static random access units are formed in the semiconductor substrate; and
the active region is a source region or a drain region of a transistor in the static random access units.

15. A metal interconnection structure, comprising:
a semiconductor substrate having active regions and an isolation structure surrounding the active regions;
a metal silicide layer formed on the active regions;
an inter metal connection layer electrically connecting with the active region formed on the isolation structure;
a dielectric layer covering the metal silicide layer, the isolation structure and the inter metal connection layer formed on the semiconductor substrate; and
a metal contact via electrically contacting with the inter metal connection layer formed in the dielectric layer.

16. The metal interconnection structure according to claim 15, wherein:
the metal contact via is completely formed on the inter metal connection layer; and
the metal contact via is electrically connected with the active region through the inter metal connection layer.

17. The metal interconnection structure according to claim 15, wherein:
the inter metal connection layer is made of Co, TiN, Ni, or Ti.

18. The metal interconnection structure according to claim 15, wherein:
the metal contact via is made of Cu, Al, or W.

19. The metal interconnection structure according to claim 15, wherein:
a diffusion barrier layer is formed on the inner surface of the contact hole.

20. The metal interconnection structure according to claim 15, wherein:
the active region is a source region or a drain region of a transistor in a static random access unit formed in the semiconductor substrate; and
a gate structure of the transistor is formed on a surface of the semiconductor substrate.
